(19) United States
(12) Patent Application Publication
(10) Pub. No.: US 2017/0149178 A1
(43) Pub. Date: May 25, 2017

(54) VIBRATION RESISTANT GROUNDING SPRING

(71) Applicant: SYMBOL TECHNOLOGIES, LLC, LINCOLNSHIRE, IL (US)

(72) Inventors: YANMIN MAO, Brampton (CA); ZHIMING ZHANG, Richmond Hill (CA)

(21) Appl. No.: 14/947,308

(22) Filed: Nov. 20, 2015

(51) Int. Cl. H01R 13/652; H05K 5/00; H01R 4/48

(52) U.S. Cl. CPC H01R 13/652; H01R 4/48; H05K 5/0086

(57) ABSTRACT

Described herein is a vibration resistant grounding spring. One embodiment takes the form of a mobile electronic device that includes an outer-bezel frame, a circuit-board frame, and a vibration resistant grounding spring. The grounding spring having a channel portion configured to receive an edge of a circuit board frame and a deflection portion extending from the channel portion. The deflection portion is configured to exert a pressure outward from the circuit-board frame towards an outer-bezel frame. The grounding spring provides for both relative motion and electrical connectivity between the circuit board and the outer-bezel frame.

### BACKGROUND OF THE INVENTION

Mobile electronic devices are widely used products. To increase durability, mechanical shock isolation is used to protect the delicate internals of the mobile electronic devices. However, mechanical shock isolation devices may not provide proper grounding paths between the delicate internals of the mobile electronic devices and the outer frame.

### BRIEF DESCRIPTION OF THE SEVERAL VIEWS OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 depicts a grounding spring, in accordance with some embodiments.

FIG. 2 depicts a grounding spring, in accordance with some embodiments.

FIG. 3 depicts a block diagram of a mobile electronic device, in accordance with some embodiments.

FIG. 4A depicts an unassembled view of a mobile electronic device, in accordance with some embodiments.

FIG. 4B depicts a first view of portions of a stack assembly, in accordance with some embodiments.

FIG. 4C depicts a second view of portions of a stack assembly, in accordance with some embodiments.

FIG. 4D depicts a third view of portions of a stack assembly, in accordance with some embodiments.

FIG. 5 depicts multiple views of portions of a mobile electronic device under different conditions, in accordance with some embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

One embodiment takes the form of a mobile electronic device that includes an outer-bezel frame; a circuit-board frame having at least one edge; at least one grounding spring having (i) a channel portion and (ii) a deflection portion, wherein: the deflection portion is configured to exert a pressure outward from the circuit-board frame, and the channel portion has two substantially parallel walls configured to receive therebetween an edge of the circuit-board frame; wherein the deflection portion extends from one of the two walls of the channel portion; and a circuit board configured to attach to the circuit-board frame, wherein: the outer-bezel frame is configured to exert a counter-pressure towards the circuit-board frame on the deflection portion of the at least one grounding spring, the at least one grounding spring provides for both relative motion and electrical connectivity between the circuit board and the outer-bezel frame.

In at least one embodiment, the circuit-board frame has first and second edges on respective opposing sides of the circuit-board frame; the at least one grounding spring comprises first and second grounding springs; and the respective channel portion of the first and second grounding springs receives the first and second edges, respectively.

In at least one embodiment, the at least one grounding spring has a retention slot configured to receive a retention tab.

In at least one embodiment, the mobile electronic device further includes a means to attach the at least one grounding spring to the circuit-board frame. In one embodiment the means to attach the at least one grounding spring includes a respective screw configured to be inserted into a respective through hole on the at least one grounding spring into a respective screw hole on the circuit-board frame. In another embodiment, the means to attach the at least one grounding spring includes a rivet for attaching the at least one grounding spring to the circuit-board frame.

In at least one embodiment, the mobile electronic device further includes a means to constrain the grounding spring along the edge of the circuit-board frame.

In at least one embodiment, the at least one grounding spring provides for electrical connectivity between the circuit board and the outer-bezel frame via a direct electrical connection between the at least one grounding spring and the circuit board.

In at least one embodiment, the at least one grounding spring provides for electrical connectivity between the circuit board and the outer-bezel frame via an indirect electrical connection between the at least one grounding spring and the circuit board by way of the circuit-board frame. In another such an embodiment, the at least one grounding spring also provides for electrical connectivity between the circuit board and the outer-bezel frame via a direct electrical connection between the at least one grounding spring and the circuit board.

In at least one embodiment, the mobile electronic device further includes a rubber shock absorber positioned between the circuit-board frame and the outer-bezel frame. In another such embodiment, the rubber shock absorber comprises at least one cutaway, and the at least one grounding spring is configured to extend outward from the circuit-board frame through the at least one cutaway. In one such embodiment, the exerted counter-pressure compresses the deflection portion of the at least one grounding spring to be substantially the same distance from the circuit-board frame as an outer perimeter of the rubber shock absorber.

In at least one embodiment, at least part of the channel portion of the at least one grounding spring is disposed between the circuit board and the circuit-board frame.

In at least one embodiment, the deflection portion of the at least one grounding spring comprises a plurality of spaced-apart deflection elements.

In another embodiment, a grounding spring includes: a channel portion; and a deflection portion, wherein: the deflection portion comprises a plurality of spaced-apart deflection elements, the deflection portion is configured to (i) exert a pressure outward from a circuit-board frame and (ii) receive a counter-pressure toward the circuit-board frame from an outer-bezel frame, the circuit-board frame is attached to a circuit board, the channel portion has two substantially parallel walls configured to receive therebetween an edge of the circuit-board frame, the deflection portion extends from one of the two walls of the channel portion, and the grounding spring provides for both relative motion and electrical connectivity between the circuit board and the outer-bezel frame.

In at least one embodiment the grounding spring further includes a retention slot configured to receive a retention tab.

In at least one embodiment, at least part of the channel portion of the grounding spring is configured to be disposed between the circuit-board frame and the circuit board.

In at least one embodiment, the grounding spring further includes a grounding-spring hole located on the channel portion of the grounding spring.

In at least one embodiment, the grounding spring provides for electrical connectivity between the circuit board and the outer-bezel frame via one or both of (i) a direct electrical connection between the grounding spring and the circuit board and (ii) an indirect electrical connection between the grounding spring and the circuit board by way of the circuit-board frame.

In another embodiment, a grounding spring includes a channel portion; and a deflection portion, wherein: the deflection portion is configured to (i) exert a pressure outward from a circuit-board frame and (ii) receive a counter-pressure toward the circuit-board frame from an outer-bezel frame, the circuit-board frame is attached to a circuit board, the channel portion has two substantially parallel walls configured to receive therebetween an edge of the circuit-board frame, the deflection portion extends from one of the two walls of the channel portion, and the grounding spring provides for both relative motion and electrical connectivity between the circuit board and the outer-bezel frame.

In at least one embodiment the grounding spring further includes a retention slot configured to receive a retention tab.

Another embodiment takes the form of a system that includes a communication interface, a processor, and data storage containing instructions executable by the processor for carrying out at least the functions described in the preceding paragraph.

Moreover, any of the variations and permutations described herein can be implemented with respect to any embodiments, including with respect to any method embodiments and with respect to any system embodiments. Furthermore, this flexibility and cross-applicability of embodiments is present in spite of the use of slightly different language (e.g., process, method, steps, functions, set of functions, and the like) to describe and or characterize such embodiments.

Before proceeding with this detailed description, it is noted that the entities, connections, arrangements, and the like that are depicted in and described in connection with the various figures are presented by way of example and not by way of limitation. As such, any and all statements or other indications as to what a particular figure “depicts,” what a particular element or entity in a particular figure “is” or “has,” and any and all similar statements—that may in isolation and out of context be read as absolute and therefore limiting—can only properly be read as being constructively preceded by a clause such as “In at least one embodiment, . . . .” And it is for reasons akin to brevity and clarity of presentation that this implied leading clause is not repeated ad nauseum in this detailed description.

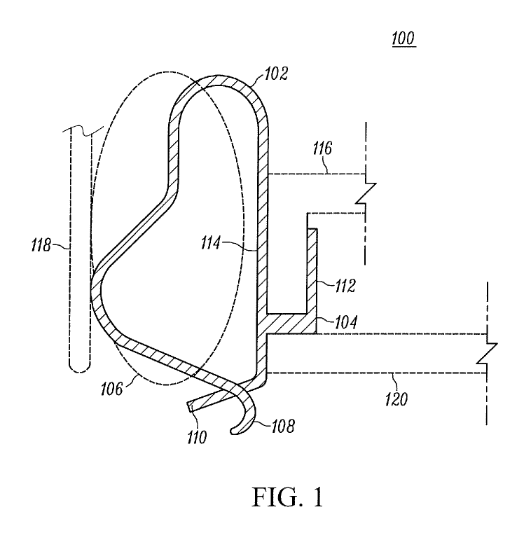

FIG. 1 depicts a grounding spring, in accordance with some embodiments. In particular, FIG. 1 depicts a view 100. The view 100 comprises a grounding spring 102 that includes a channel portion 104 and a deflection portion depicted generally at 106, a retention tab 108, a retention slot 110, and channel walls 112 and 114. The view 100 also includes a circuit-board frame 116, an outer-bezel frame 118, and a circuit board 120. The view 100 is a cross-sectional view of the grounding spring 102 in relation to other components of a mobile electronic device, such as the circuit-board frame 116, the outer-bezel frame 118, and the circuit board 120.

The grounding spring 102 includes the channel portion 104. The channel portion has two walls 112 and 114. As shown in the view 100, the two walls 112 and 114 are substantially parallel and are configured to receive therebetween the two walls of an edge of the circuit-board frame 116. The walls 112 and 114 may be configured in an arrangement other than substantially parallel in order to receive the edge of the circuit-board frame. For example, the walls 112 and 114 may be slightly tapered to conform to a tapered shape of the circuit board frame or to provide a clamping pressure on the circuit-board frame.

The grounding spring 102 further includes a deflection portion 106, extending from the channel portion 104. The deflection portion 106 is configured to (i) exert a pressure outward from the circuit-board frame 116 and (ii) receive a counter-pressure from the outer-bezel frame 118 towards the circuit-board frame 116. Although not shown in view 100, the circuit-board frame 116 is able to be attached to the circuit board 120.

The grounding spring 102 provides for both relative motion and electrical connectivity between the circuit board 120 and the outer-bezel frame 118. To provide for relative motion, the deflection portion 106 of the grounding spring 102 exerts a pressure towards the outer-bezel frame 118. When the outer-bezel frame is moved, for example under a mechanical shock, the deflection portion 106 deflects or extends, allowing the outer-bezel frame 118 to move relative to the circuit-board 120.

To provide for electrical connectivity, the grounding spring 102 and the outer-bezel frame are manufactured from a conductive material. The outer-bezel frame 118 is in contact with the deflection portion 106 of the grounding spring 102, establishing electrical connectivity between the two. Electrical conductivity between the grounding spring 102 and the circuit board 120 may be direct from the channel portion 104 of the grounding spring 102 to a grounding path on the circuit board 120, or indirect by way of the circuit-board frame 116, or both. In the indirect path, the channel portion 104 is in electrical contact with the circuit-board frame 116, and the circuit-board frame is configured to be electrically connected to the circuit board 120.

In some embodiments, the grounding spring 102 further includes the retention tab 108 and the retention slot 110. The retention slot 110 is configured to receive the retention tab 108. The retention tab 108 is also configured to be uncoupled from the retention slot 110. Although the view 100 depicts the retention tab 108 located near the deflection portion 106 and the retention tab 110 near the channel portion 104, the locations of the retention slot 110 and the retention slot 108 may be reversed in an embodiment.

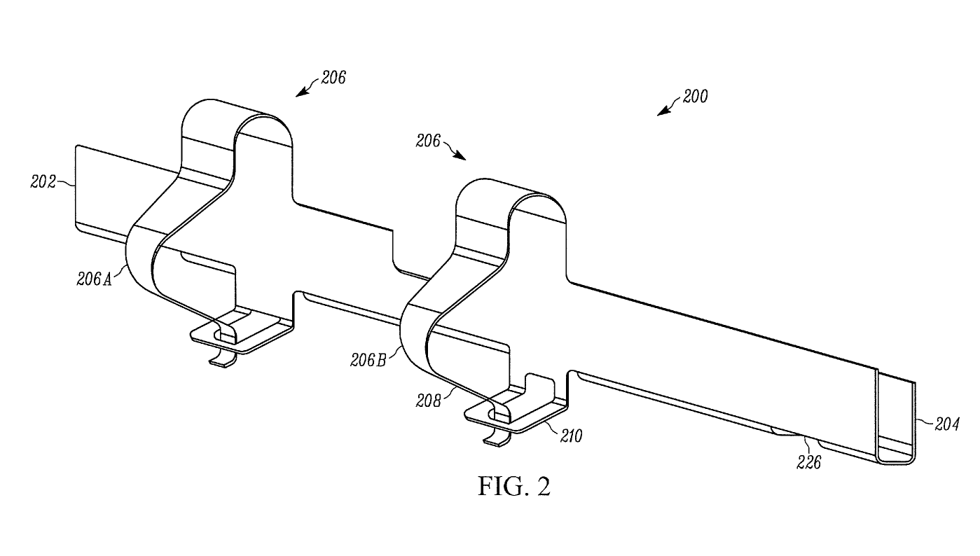

The grounding spring 102 may further include a grounding-spring hole on the channel portion 104 between the walls 112 and 114. The functions of the grounding spring hole are similar to the functions of the grounding spring hole 226 discussed in FIG. 2 and throughout the application.

FIG. 2 depicts a grounding spring, in accordance with an embodiment. In particular, HG. 2 depicts a view 200. The view 200 is a perspective view of a grounding spring 202. The grounding spring 202 comprises a channel portion 204, a deflection portion 206, the deflection portion 206 comprising multiple deflection elements 206A and 206B spaced apart along the channel portion 204 that includes a grounding-spring hole 226, a retention slot 208, and a retention tab 210.

While only the grounding spring 202 is depicted in FIG. 2, it is configured to interact with a circuit-board frame, a circuit board, and an outer-bezel frame similarly to the grounding spring 102 depicted in FIG. 1. Additionally, the elements of the grounding spring 202 carry out similar functions as the elements of grounding spring 102 depicted in FIG. 1.

The channel portion 204 is configured to receive an edge of a circuit-board frame. At least part of the channel portion 204 is configured to be disposed between a circuit-board frame and a circuit board. Each deflection element 206A and 206B of the deflection portion 206 is configured to exert a pressure towards an outer-bezel frame and away from a circuit-board frame. In some embodiments, the grounding spring 202 further comprises the retention slot 208 configured to be receive the retention tab 210 on some or all of the deflection elements.

The channel portion 204 may also include the grounding-spring hole 226. The grounding-spring hole 226 is located between the channel walls. In some embodiments, the grounding-spring hole 226 is configured to receive a tab located on the edge of the circuit-board frame. The dimensions of the grounding-spring hole 226 may correspond to the dimensions of the tab to ensure a tight fit. The grounding-spring hole 226 permits proper alignment during assembly of a mobile electronic device and constrains the grounding spring from sliding along the edge of the circuit-board frame when the tab is received. The grounding spring 202 may include a plurality of grounding-spring holes 226, each configured to receive a tab.

The grounding spring 202 provides for both relative motion and electrical connectivity between a circuit board and an outer-bezel frame. Similar to the grounding spring 102, the grounding spring 202 has the deflection portion 206. The deflection portion 206 has a plurality of space apart deflection elements 206A and 206B. The electrical connectivity can be provided through any one of the plurality of deflection elements.

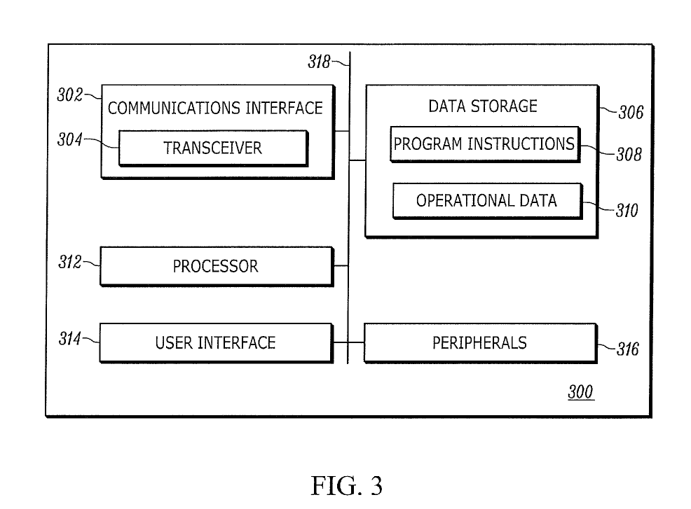

FIG. 3 depicts a block diagram of a mobile electronic device, in accordance with some embodiments. In particular, FIG. 3 depicts a mobile electronic device 300. The mobile electronic device 300 may be configured to incorporate the grounding spring of this disclosure.

The mobile electronic device 300 includes a communications interface 302 (that includes a transceiver 304), data storage 306 (that contains program instructions 308 and operational data 310), a processor 312, a user interface 314, peripherals 316, and a communication bus 318. This arrangement is presented by way of example and not limitation, as other example arrangements could be described here.

The communication interface 302 includes the transceiver 304. The transceiver 304 may be configured (e.g., tuned) to receive and transmit on one of a set of channels. The transceiver 304 may be a single component, or realized as a separate transmitter and receiver, as known by those with skill in the art. The communication interface 302 may be configured to be operable for communication according to one or more wireless-communication protocols, some examples of which include LMR, LTE, APCO P25, ETSI DMR, TETRA, Wi-Fi, Bluetooth, NFC, and the like. The communication interface 302 may also include one or more wired-communication interfaces (for communication according to, e.g., Ethernet, USB, and/or one or more other protocols.) The communication interface 302 may include any necessary hardware (e.g., chipsets, antennas, Ethernet interfaces, etc.), any necessary firmware, and any necessary software for conducting one or more forms of communication with one or more other entities as described herein.

The data storage 306 may take the faun of any non-transitory computer-readable medium or combination of such media, some examples including flash memory, read-only memory (ROM), and random-access memory (RAM) to name but a few, as any one or more types of non-transitory data-storage technology deemed suitable by those of skill in the relevant art could be used. As depicted in FIG. 3, the data storage 306 contains program instructions 308 executable by the processor 312 for carrying out various functions described herein, and further is depicted as containing and operational data 310, which may include any one or more data values stored by and/or accessed by the computing device in carrying out one or more of the functions described herein.

The processor 312 may include one or more processors of any type deemed suitable by those of skill in the relevant art, some examples including a general-purpose microprocessor and a dedicated digital signal processor (DSP).

The user interface 314 may include one or more input devices (a.k.a. components and the like) and/or one or more output devices (a.k.a. components and the like.) With respect to input devices, the user interface 314 may include one or more touchscreens, buttons, switches, microphones, and the like. With respect to output devices, the user interface 314 may include one or more displays, speakers, light emitting diodes (LEDs), and the like. Moreover, one or more components (e.g., an interactive touchscreen and display of the user interface 314 could provide both user-input and user-output functionality. Other user interface components could also be present, as known to those of skill in the art.

The peripherals 316 may include any computing device accessory, component, or the like, that is accessible to and useable by the computing device during operation. Example peripherals 316 include a GPS receiver, an altimeter, an RSSI sensor, a scanner, and the like.

The various component of the mobile electronic device 300 are all communicatively coupled with one another via a communication bus 318 (or other suitable communication network, or the like.)

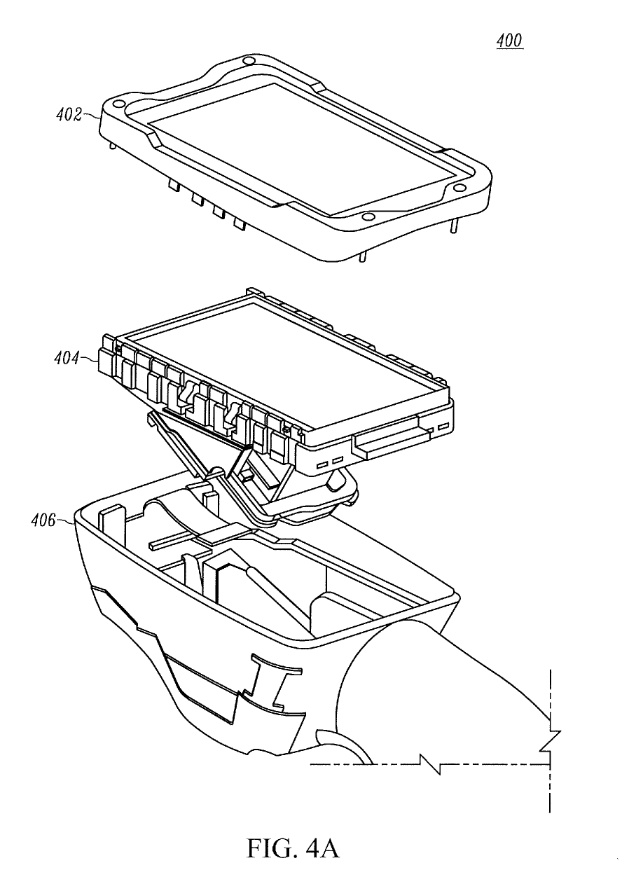

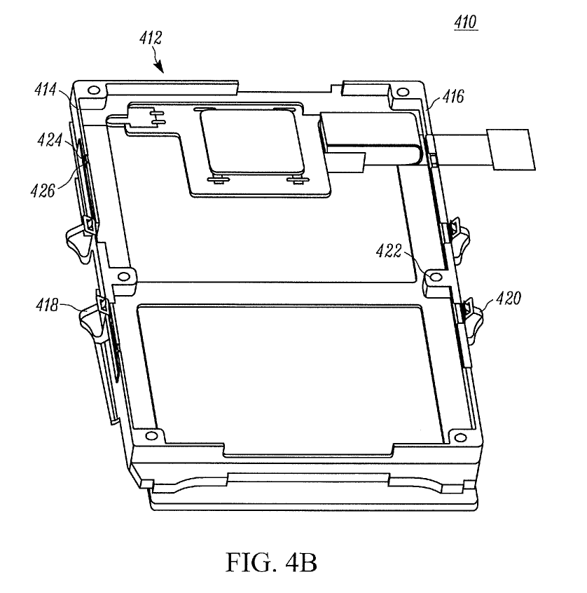

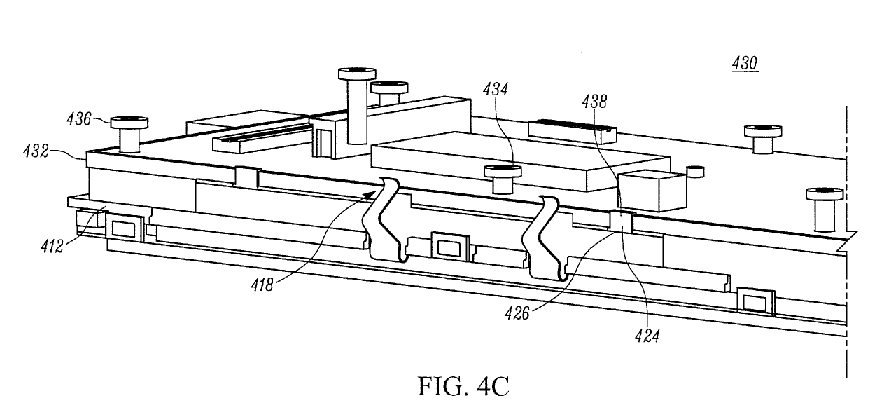

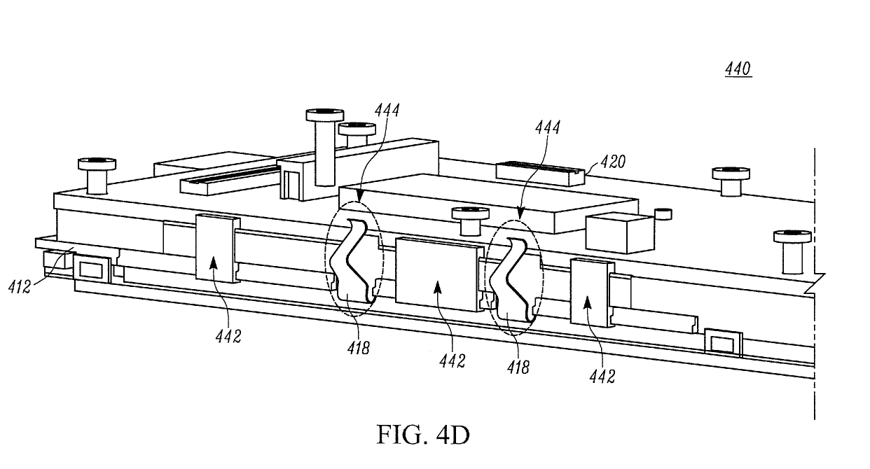

FIG. 4A depicts an unassembled view of a mobile electronic device, in accordance with some embodiments. In particular, FIG. 4A depicts a view 400. The view 400 comprises an upper housing 402, a stack assembly 404, and a lower housing 406. The mobile electronic device depicted in the view 400 may include the aspects of the mobile electronic device 300 depicted in FIG. 3. For example, the stack assembly 404 may include a printed circuit board mounted on a circuit-board frame. The processor may be mounted on the printed circuit board and be able to execute program instructions stored in a data storage and interact with a user interface, peripherals, and a communications interface through a communication bus. An assembled mobile electronic device includes the upper housing 402 connected to the lower housing 406 with the stack assembly 404 disposed between both housings.

FIGS. 4B-D depict multiple views of portions of a stack assembly, in accordance with some embodiments. The components depicted in the multiple views are portions of the stack assembly 404 depicted in FIG. 4A by way of example, and may be located in different portions of a mobile electronic device as known by those with skill in the art.

In particular, FIG. 4B depicts a first view 410. The first view 410 comprises a circuit-board frame 412 (that includes a first and a second edge, 414 and 416, respectively), a first grounding spring 418, a second grounding spring 420, a first portion of a grounding-spring-attachment means 422, a circuit-board frame tab 424, and a grounding-spring hole 426.

In the view 410, a circuit-board frame 412 includes the first edge 414 on the left side and the second edge 416 on the right side. The first grounding spring 418 is configured to receive the first edge 414 between two substantially parallel walls on a channel portion of the first grounding spring 418. The second grounding spring 420 is configured to receive the second edge 416 between two substantially parallel walls on a channel portion of the second grounding spring 420. The circuit-board-frame tab 424 extends from the edge of the circuit-board frame. The grounding-spring hole 426 is on the channel portion of the grounding spring between the two substantially parallel walls.

Although the view 410 depicts multiple grounding springs with each of the grounding springs representative of the grounding spring 202 depicted in FIG. 2, only a single grounding spring may be used. Additionally, the grounding spring may be representative of the grounding spring 102 depicted in FIG. 1. The grounding spring or springs may be placed on any or all of the circuit-board edges, to include on opposing edges (as depicted in the view 410), or adjoining edges.

The first portion of the grounding-spring-attachment means 422 includes a screw hole on the circuit-board frame and a complimentarily sized through hole on the grounding spring.

The circuit-board frame may also include a means for constraining the grounding spring to prevent the channel portion from sliding along the edge of the circuit-board frame. The means to constrain the grounding spring may include an indentation on the edge of the circuit-board frame configured to the dimensions of the grounding spring.

The means to constrain the grounding spring channel portion from sliding along the edge of the circuit-board frame may also include the circuit-board-frame tab 424 configured to be inserted through the grounding-spring hole 426.

FIG. 4C depicts a second view of portions of a stack assembly, in accordance with some embodiments. In particular, FIG. 4C depicts the view 430. The view 430 includes the elements from the view 410, a circuit-board 432 that includes a circuit-board notch 438, a second portion of a grounding-spring-attachment means 434, a screw 436, the circuit-board-frame tab 424, the grounding-spring hole 426, and a circuit-board notch 438.

Part of the channel portion of the first grounding spring 418 is disposed (e.g., sandwiched) between the circuit-board frame 412 and the circuit board 432.

The second portion of the grounding-spring-attachment means 434 includes a screw. The first and second portions of the grounding-spring-attachment means (422 and 434) combine to provide for a screw to pass through the through hole on a grounding spring into a screw hole on the circuit-board frame. The screw that is part of the second portion of the grounding-spring-attachment means 434 may also pass through a hole in a printed circuit board as a means to attach the circuit board to the circuit-board frame.

The screw 436 is configured to pass through a hole in the printed circuit board 432 and screw into the circuit-board frame 412 as an example means to attach the circuit board 432 to the circuit-board frame 412.

Alternate means to attach a grounding spring to a circuit-board frame include a rivet for attaching the grounding spring to the circuit-board frame, a weld, or an adhesive, among other possibilities. The grounding-spring-attachment means may also serve as a means to constrain the grounding spring from sliding along the edge of the circuit-board frame.

The circuit-board-frame tab 424 may extend from the edge a sufficient distance to receive both the grounding-spring hole 426 and the circuit-board notch 438. During assembly, the circuit-board-frame tab 424 receives the grounding-spring hole 426 and the circuit-board notch 438 to ensure proper alignment of the grounding spring and the circuit board, respectively, along the edge of the circuit-board frame. Once assembled, the circuit-board-frame tab 424 extends through the grounding-spring hole 426 and the circuit-board notch 438 to constrain the grounding spring from sliding along the circuit-board-frame edge.

FIG. 4D depicts a third view of portions of a stack assembly, in accordance with some embodiments. In particular, FIG. 4D depicts a view 440. The view 440 includes the elements from the view 430, a rubber shock absorber 442, and rubber-shock-absorber cutaways 444. The rubber-shock-absorber cutaways 444 are configured to permit the deflection portions of the grounding springs 418 and 420 to pass through and contact the outer-bezel frame when installed.

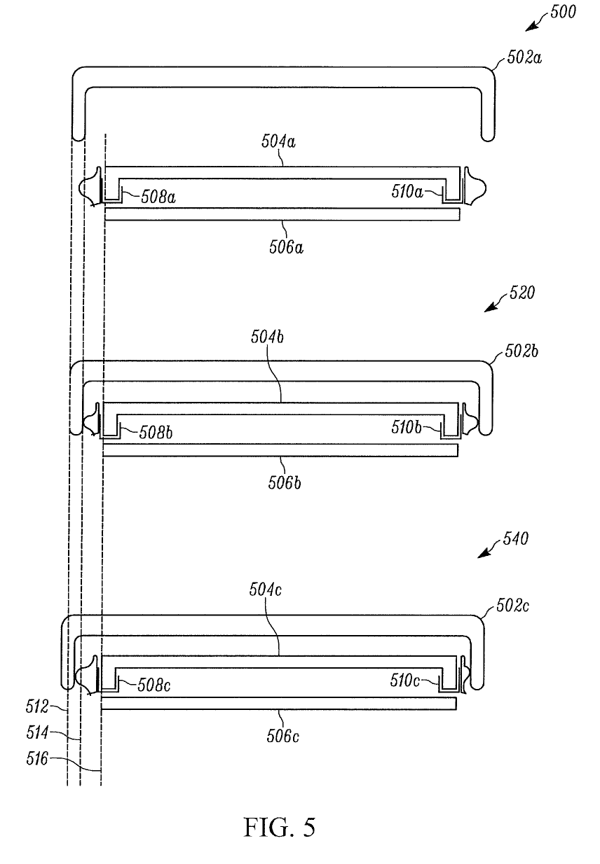

FIG. 5 depicts multiple views of portions of a mobile electronic device under different conditions, in accordance with some embodiments. In particular, FIG. 5 depicts a view 500, a view 520, and a view 540. Each of the views comprise the same elements, however, each view depicts the stack assembly portions under a different condition. Each view includes an outer-bezel frame 502, a circuit-board frame 504, a circuit board 506, a first grounding spring 508, and a second grounding spring 510.

For purposes of clarity, in FIG. 5 and in this accompanying description, the elements in the view 500 are denoted using an “a” (e.g., the outer-bezel frame 502a), the elements in the view 520 using a “b” (e.g., the outer-bezel frame 502b), and the elements in the view 540 using a “c” (e.g., the outer-bezel frame 502b). Moreover, passing through all three of the views are three dotted reference lines 512, 514, and 516 to show the relative movement of the elements in the different views.

In each view, part of the channel portion of each grounding spring (508 and 510) receives, between two of its substantially parallel walls, an edge of the circuit-board frame 504. Also, each of the grounding springs (508 and 510) are disposed between the circuit-board frame 504 and the circuit board 506. For clarity, other elements of the mobile electronic device are not displayed in FIG. 5.

By way of example, the outer-bezel frame 502 may be a portion of the upper housing 402 depicted in FIG. 4A, and the circuit-board frame 504, circuit board 506, and the grounding springs 508 and 510 may be a portion of the stack assembly 404 depicted in FIG. 4A.

The view 500 depicts the outer-bezel frame 502a in an unmated position. With the outer-bezel frame 502a above the stack assembly, the deflection portion of the grounding spring 508a is not depressed, and the deflection portion extends at least past the dotted reference line 514. Similarly, the deflection portion of the grounding spring 510a is also not depressed.

The view 520 depicts the outer-bezel frame 502b in a mated position. With the outer-bezel frame 502b mated to the stack assembly, the deflection portion of the grounding spring 508b is depressed towards the circuit-board frame 504b to the dotted reference line 514. Similarly, the grounding spring 512b is also depressed by the outer-bezel frame 502b. The outer-bezel frame 502b may depress the grounding springs 508b and 510b, or extension tabs on the outer-bezel frame may be used interact with the grounding springs.

In at least one embodiment, a rubber shock absorber is positioned between the circuit-board frame and the outer-bezel frame. In such an embodiment, the rubber shock absorber may comprise at least one cutaway, and at least one grounding spring is configured to extend outward from the circuit-board frame through the at least one cutaway. Although not shown on FIG. 5, in some embodiments, the rubber shock absorber is positioned between the circuit-board frame 504 and the outer bezel frame 502. In the view 520, with the outer-bezel frame 502b installed on the stack assembly, an outer perimeter of the rubber shock absorber may extend away from the circuit-board frame to the dotted reference line 514, in line with the deflection portion of the grounding spring 508b and the inside wall of the outer-bezel frame 502b.

The view 540 depicts the outer-bezel frame 502c in a mated position and shifted to the left, depicting relative motion between the outer-bezel frame 502 and the circuit board 506 between the view 520 and the view 540. In each of the views 500, 520, and 540, the circuit-board frame 504 and the circuit board 506 are in a constant position and have a left edge in line with the dotted reference line 516. However, the outer-bezel frame 512 is shifted to the left between the view 520 and the view 540. In the view 520, the interior wall of the outer-bezel frame 502b is in line with the dotted reference line 514. In the view 540, the interior wall of the outer-bezel frame 502c is to the left of the dotted reference line 514. The deflection portion of the grounding spring 508c is depressed less and extends to the left of the dotted reference line 514 to maintain contact with the interior wall of the outer-bezel frame 502c. Conversely, the grounding spring 512c is depressed more due to the shift in the outer-bezel frame 502c.

In each of the view 520 and the view 540, the deflection portion of the grounding springs (508 and 510) are in contact with an interior wall of the outer-bezel frame 502. This contact between the deflection portion of the grounding spring and the outer-bezel frame provides for electrical continuity between the outer-bezel frame and the grounding spring. Additionally, there is electrical continuity between the grounding spring and the circuit board 506, either directly to the circuit board or by way of the circuit-board frame 504, or both.

Although the views in FIG. 5 depict a plurality of grounding springs, each in contact with the outer-bezel frame throughout relative motion between the outer-bezel frame and the circuit board, this is by way of example. Other variations may be implemented to include use of a single grounding spring, the use of a plurality of grounding springs, wherein at least one of the plurality of grounding springs maintains electrical contact throughout different shock and relative motion conditions between the outer-bezel frame and the circuit board, or other similar configurations.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the terms is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

We claim:

1. A mobile electronic device comprising:
an outer-bezel frame;
a circuit-board frame having at least one edge;
at least one grounding spring having (i) a channel portion and (ii) a deflection portion, wherein:
the deflection portion is configured to exert a pressure outward from the circuit-board frame,
the channel portion has two substantially parallel walls configured to receive therebetween an edge of the circuit-board frame,
the deflection portion extends from one of the two walls of the channel portion; and
a circuit board configured to attach to the circuit-board frame, wherein:
the outer-bezel frame is configured to exert a counter-pressure towards the circuit-board frame on the deflection portion of the at least one grounding spring,
the at least one grounding spring provides for both relative motion and electrical connectivity between the circuit board and the outer-bezel frame.

2. The mobile electronic device of claim 1, wherein:
the circuit-board frame has first and second edges on respective opposing sides of the circuit-board frame;
the at least one grounding spring comprises first and second grounding springs; and
the respective channel portion of the first and second grounding springs receives the first and second edges, respectively.

3. The mobile electronic device of claim 1, wherein the at least one grounding spring has a retention slot configured to receive a retention tab.

4. The mobile electronic device of claim 1, further comprising a means to attach the at least one grounding spring to the circuit-board frame.

5. The mobile electronic device of claim 4, wherein the means to attach the at least one grounding spring comprises a respective screw configured to be inserted into a respective through hole on the at least one grounding spring into a respective screw hole on the circuit-board frame.

6. The mobile electronic device of claim 1, further comprising a means to constrain the grounding spring from sliding along the edge of the circuit-board frame.

7. The mobile electronic device of claim 1, wherein the at least one grounding spring provides for electrical connectivity between the circuit board and the outer-bezel frame via a direct electrical connection between the at least one grounding spring and the circuit board.

8. The mobile electronic device of claim 1, wherein the at least one grounding spring provides for electrical connectivity between the circuit board and the outer-bezel frame via an indirect electrical connection between the at least one grounding spring and the circuit board by way of the circuit-board frame.

9. The mobile electronic device of claim 8, wherein the at least one grounding spring also provides for electrical connectivity between the circuit board and the outer-bezel frame via a direct electrical connection between the at least one grounding spring and the circuit board.

10. The mobile electronic device of claim 1, further comprising a rubber shock absorber positioned between the circuit-board frame and the outer-bezel frame.

11. The mobile electronic device of claim 10, wherein:
the rubber shock absorber comprises at least one cutaway, and
the at least one grounding spring is configured to extend outward from the circuit-board frame through the at least one cutaway.

12. The mobile electronic device of claim 11, wherein the exerted counter-pressure compresses the deflection portion of the at least one grounding spring to be substantially the same distance from the circuit-board frame as an outer perimeter of the rubber shock absorber.

13. The mobile electronic device of claim 1, wherein at least part of the channel portion of the at least one grounding spring is disposed between the circuit board and the circuit-board frame.

14. The mobile electronic device of claim 1, wherein the deflection portion of the at least one grounding spring comprises a plurality of spaced-apart deflection elements.

15. A grounding spring comprising:
a channel portion; and
a deflection portion,
wherein:
the deflection portion comprises a plurality of spaced-apart deflection elements,
the deflection portion is configured to (i) exert a pressure outward from a circuit-board frame and (ii) receive a counter-pressure toward the circuit-board frame from an outer-bezel frame,
the circuit-board frame is attached to a circuit board,
the channel portion has two substantially parallel walls configured to receive therebetween an edge of the circuit-board frame,
the deflection portion extends from one of the two walls of the channel portion, and
the grounding spring provides for both relative motion and electrical connectivity between the circuit board and the outer-bezel frame.

16. The grounding spring of claim 15, further comprising a retention slot configured to receive a retention tab.

17. The grounding spring of claim 15,
wherein:
at least part of the channel portion of the grounding spring is configured to be disposed between the circuit-board frame and the circuit board, and
the channel portion further comprises a grounding-spring hole between the two substantially parallel walls, the grounding-spring hole configured to receive a tab extending from the edge of the circuit-board frame.

18. The grounding spring of claim 15, wherein the grounding spring provides for electrical connectivity between the circuit board and the outer-bezel frame via one or both of (i) a direct electrical connection between the grounding spring and the circuit board and (ii) an indirect electrical connection between the grounding spring and the circuit board by way of the circuit-board frame.

19. A grounding spring comprising:
a channel portion; and
a deflection portion,
wherein:
the deflection portion is configured to (i) exert a pressure outward from a circuit-board frame and (ii) receive a counter-pressure toward the circuit-board frame from an outer-bezel frame,
the circuit-board frame is attached to a circuit board,
the channel portion has two substantially parallel walls configured to receive therebetween an edge of the circuit-board frame,
the deflection portion extends from one of the two walls of the channel portion, and
the grounding spring provides for both relative motion and electrical connectivity between the circuit board and the outer-bezel frame.

20. The grounding spring of claim 19, further comprising a retention slot configured to receive a retention tab.
